(19) United States
(12) Patent Application Publication
(10) Pub. No.: US 2011/0096507 A1
(43) Pub. Date: Apr. 28, 2011

(54) Microelectronic thermal interface

(75) Inventor: Brian Deram, Lincolnshire, IL (US)

(73) Assignee: Kester, Inc., Itasca, IL (US)

(21) Appl. No.: 12/807,380

(22) Filed: Sep. 2, 2010

Related U.S. Application Data
(60) Provisional application No. 61/279,638, filed on Oct. 24, 2009.

(51) Int. Cl. H05K 7/20; F28F 7/00; B23K 1/20; B23K 31/02

(52) U.S. Cl. 361/718; 165/185; 228/223; 228/141.1

(57) ABSTRACT

An improved thermal interface between an integrated circuit chip and a heat sink comprises a copper grid embedded in a layer of a solder material that has a fusion temperature higher than the maximum operating temperature of the semiconductor chip, and bonds to the semiconductor chip and the heat sink when heated to the fusion temperature of the solder material in the presence of a soldering flux. The copper grid has high thermal conductivity so that the amount of solder material needed for an efficient thermal interface is reduced and solder materials with less expensive components may be used. The copper grid also tends to mitigate local hot spots by enhancing lateral heat transfer, and inhibits solder spreading during formation of the thermal interface.

### BACKGROUND OF THE INVENTION

1. Field of the Invention

This invention is concerned with microelectronic devices, and in particular with heat dissipation for integrated circuit (IC) chips.

2. Description of the Related Art

Modern microelectronic devices generally comprise integrated circuit (IC) chips that are electrically connected via a ball grid array on the chip bottom to a printed circuit board (or another substrate) by reflow soldering. For high-speed IC chips that generate a significant amount of heat during operation, the top of the chip is generally connected to a heat sink, which may comprise a heat radiator. A thin layer of a thermal interface material (TIM) is typically placed between the top of the chip and the heat sink to improve heat transfer. A typical TIM layer comprises a pure indium foil, which is reflowed to form an intimate bond between the chip and the heat sink so as to provide good heat transfer.

As IC chips have decreased in size and increased in speed, heat dissipation has become a significant issue for the microelectronics industry. In addition, the price of indium has recently increased sharply and fluctuates greatly. There is a need for improved methods and materials for dissipation of heat from IC chips. There is also a need for TIM layers comprising materials that are less expensive than indium.

U.S. Patent Application Publication 2005/0155752 to Larson et al. describes a thermal interface comprising a copper wire mesh and a slurry of conductive particles in a liquid metal alloy designed to improve heat transfer by providing more direct contact along the entire surface of the chip via a liquid interface. U.S. Pat. No. 6,523,608 to Solbrekken et al. describes a thermal interface comprising a metallic frame (mesh) coated with a thermally conductive material that preferably melts at or below the temperature of the source (operating temperature of the IC chip). The objective in this case was to attain improved thermal transfer via a thermal interface comprising a liquid metal (at operating temperature) while avoiding use of a rigid thermally conductive adhesive or solder that could damage the chip via stresses due to a mismatch in coefficients of thermal expansion. For both of these references, a metal mesh or grid was employed as a means of containment to prevent the liquid metal from spreading and producing electrical shorts in adjacent circuit components.

These prior art approaches to improving the performance of microelectronic thermal interfaces have the drawbacks that the liquid metal tends to be difficult to contain and is prone to oxidation that can lower the heat transfer efficiency. These references teach that thermal interfaces involving solid materials are inefficient and unreliable. The present inventor has found that this need not be the case.

### SUMMARY OF THE INVENTION

The present invention provides an improved thermal interface between an integrated circuit (IC) chip and a heat sink, as well as a preform for forming the improved thermal interface, and methods for fabricating the preform and the improved thermal interface. The thermal interface of the invention comprises a layer of a solder material sandwiched between and bonded to the IC chip and the heat sink, and a metallic grid embedded in the layer of the solder material. The solder material has a fusion temperature that is higher than a predetermined maximum operating temperature of the IC chip, and the metallic grid comprises a metal having a fusion temperature higher than the fusion temperature of the solder material. Preferred solder materials include indium and indium-tin alloys. A preferred metallic grid comprises copper metal. In one embodiment, the metallic grid comprises a mesh of woven metal wires, whose pitch may be varied to avoid stray wires at the edges of preforms, for example. In another embodiment, the metallic grid comprises a perforated metal foil, whose holes or openings may be of any suitable geometric shape, square or circular, for example.

The preform of the invention for providing an improved thermal interface between an IC chip and a heat sink, comprises a sheet of a solder material that has a fusion temperature higher than a predetermined maximum operating temperature of the IC chip. The preform further comprises a metallic grid that is embedded in the sheet of the solder material and comprises a metal having a fusion temperature higher than the fusion temperature of the solder material. The solder material of the preform bonds to the IC chip and the heat sink when the preform is sandwiched therebetween and heated to the fusion temperature of the solder material in the presence of a soldering flux.

The method of the invention for fabricating a preform to provide an improved thermal interface between an IC chip and a heat sink comprises the steps of providing a solder material that has a fusion temperature higher than a predetermined maximum operating temperature of the IC chip, providing a metallic grid of a metal having a fusion temperature higher than the fusion temperature of the solder material, and embedding the metallic grid within the solder material. The solder material of the preform bonds to the IC chip and the heat sink when heated to the fusion temperature of the solder material in the presence of a soldering flux. The metallic grid and the solder material comprising the preform may be sized and precisely aligned prior to assembly so as to minimize subsequent processing of the preform, or a plurality of preforms may be fabricated from a larger preform sheet, by cutting, slicing, stamping or die punching, for example.

The metallic grid may be embedded in the soldering material to form a preform according to the invention by any suitable method. In one embodiment, for example, the metallic grid is embedded within a sheet of the solder material by applying a soldering flux to at least a portion of the surface of the metallic grid, the sheet of the solder material, or both the metallic grid and the sheet of the solder material, placing the sheet of the solder material and the metallic grid in contact to form a layered preform precursor, and heating the layered preform precursor to the fusion temperature of the solder material. In an alternative embodiment, the metallic grid is pressed into a layer of the solder material by applying pressure via platens or rollers, for example. In another embodiment, the metallic grid is embedded in the solder material by depositing the solder material onto the metallic grid by dip coating, electrodeposition, vapor deposition, or a combination thereof. For embodiments involving an electrodeposited or vapor-deposited coating, a soldering flux is not required to fabricate the preform but the coated preform may be reflowed, with or without a soldering flux, to provide a more uniform and/or protective layer of the solder material.

The method of the invention for providing an improved thermal interface between an IC chip and a heat sink comprises the steps of providing a preform according to the invention, applying a soldering flux to at least one of the IC chip, the heat sink, and the two sides of the preform, placing the preform between and in contact with the IC chip and the heat sink to provide a thermal interface precursor, and heating the thermal interface precursor to a predetermined temperature higher than the fusion temperature of the solder material.

The thermal interface of the invention, which comprises a metallic grid embedded in a layer of solder material sandwiched between and bonded to an IC chip and a heat sink, provides significant cost and performance advantages compared to prior art thermal interfaces. The metallic grid preferably comprises copper or another metal of high thermal conductivity and relatively low costs. In this case, heat transfer across the thermal interface may be enhanced and/or the required amount of the solder material and its cost may be reduced. Further cost savings may be realized by employing solder materials with less expensive components. The metallic grid also tends to mitigate local hot spots by enhancing lateral heat transfer so that the IC chip operates at a lower overall temperature for which its efficiency is higher.

During fabrication of the thermal interface by fusion of the solder material, the metallic grid mitigates solder bleed out by retaining the molten solder and prevents solder squeeze out by resisting compression that would otherwise result from the weight of the heat sink (and pressure from any holddown spring used). By mitigating solder bleed out and solder squeeze out, the invention also allows the circuit density of microelectronic devices to be increased by placing components closer together (reducing the size of the keep out area). In addition, the resistance to compression provided by the metallic grid of the invention obviates the need to provide such resistance by hardening the seal material of a heat spreader type of heat sink prior to reflowing the solder material of the thermal interface. This enables the preheat time of the reflow process to be shortened so as to increase process throughput and reduce costs.

Furthermore, the metallic grid of the invention tends to enhance performance of the thermal interface by reducing the size and frequency of voids in the solder material. Such voids typically result from entrapment of gas bubbles during reflow of the solder material to fabricate a preform and/or a thermal interface according to the invention. The metallic grid reduces the opportunity for voids to form by displacing some of the solder material in the thermal interface. In addition, wetting of the metallic grid during reflow of the solder material during fabrication of a preform helps dislodge gas bubbles, which in the presence of a metallic grid are generally also closer to the preform surface.

Use of a perforated metal foil instead of a woven mesh for the metallic grid may further suppress void formation by eliminating wire cross-over points that may trap gas bubbles. A perforated metal foil also offers the advantage of being flatter than a woven mesh so that the thermal interface can be made thinner for improved thermal transfer efficiency.

Further features and advantages of the invention will be apparent to those skilled in the art from the following detailed description, taken together with the accompanying drawings.

### BRIEF DESCRIPTION OF THE DRAWINGS

FIG. 1 depicts a side view of a typical prior art thermal interface between a heat sink and an IC chip attached to a substrate via an array of solder balls.

FIG. 2 illustrates the effects of bleed out or squeeze out of solder from a thermal interface for a BGA device.

FIG. 3 depicts a side view of a thermal interface of the invention connecting a heat sink and an IC chip attached to a substrate via an array of solder balls.

FIG. 4 depicts a side view of a thermal interface of the invention connecting a heat spreader to an IC chip attached to a substrate via an array of solder balls.

FIG. 5 illustrates two types of metallic grids suitable for use in the thermal interface of the invention.

FIG. 6 depicts a preform of the invention comprising a wire mesh embedded in a layer of a solder material.

FIG. 7 illustrates a general method for embedding a metallic grid in a layer of a solder material by reflow soldering in the presence of a soldering flux to provide a preform for use in fabricating the thermal interface of the invention.

FIG. 8 depicts fabrication of the preform of the invention by a ribbon to ribbon compression and reflow process.

FIG. 9 depicts fabrication of the thermal interface of the invention using a preform according to the invention.

FIG. 10 depicts a metal mesh having periodically varied wire pitch to avoid stray wires during fabrication of the preform of the invention.

FIG. 11 depicts a metal mesh that is bias cut to avoid stray wires during fabrication of the preform of the invention.

These figures are schematic representations and are not to scale. Some features have been enlarged for better depiction of the features and operation of the invention.

### DETAILED DESCRIPTION OF THE INVENTION

Technical terms used in this document are generally known to those skilled in the art. The term “heat sink” is used in the general sense and encompasses any means of dissipating heat, including a heat pipe, a slug, a radiator, a heat spreader, and combinations thereof, for example. The terms “integrated circuit chip”, “IC chip” and “semiconductor chip” are equivalent. An IC chip is typically packaged as a ball grid array (BGA) for which the input/output connections are made via reflow soldering of solder balls (spheres) in an array on the bottom side of the IC chip. The BGA may be attached directly to a circuit board, or to a chip carrier attached to a circuit board. The thermal interface material (TIM) is bonded to the top surface of the IC chip opposite to the BGA side. The term “bonded” denotes strong attachment, usually involving soldering with formation of an intermetallic compound layer at the interface. The term “metal” includes both pure metals and alloys.

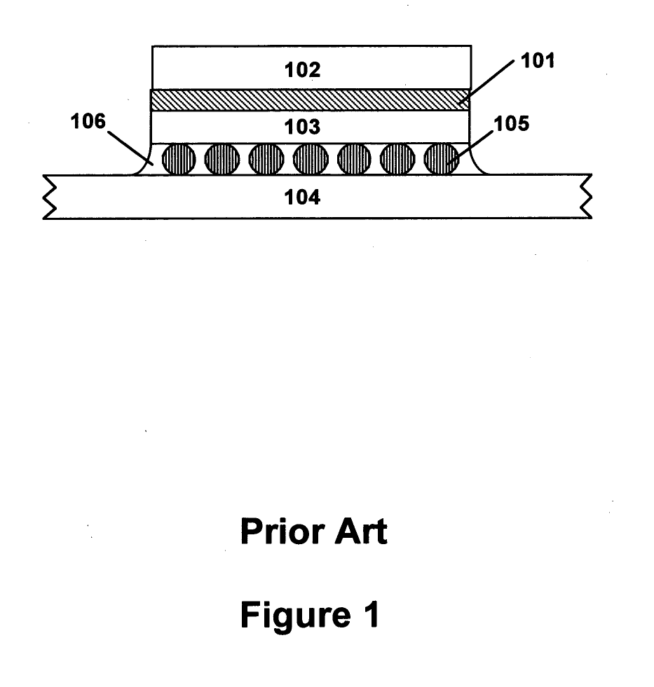

FIG. 1 depicts a side view of a typical prior art thermal interface 101 between a heat sink 102 and an IC chip 103 attached to a substrate 104 via an array of solder balls 105 that are reinforced and protected by a resin underfill 106. Thermal interface 101 typically comprises a layer of indium solder, which is expensive and when fused during soldering process tends to bleed out of the thermal interface due to surface tension effects and to be squeezed out of the thermal interface under the weight of heat sink 102 (and pressure from any holddown spring used).

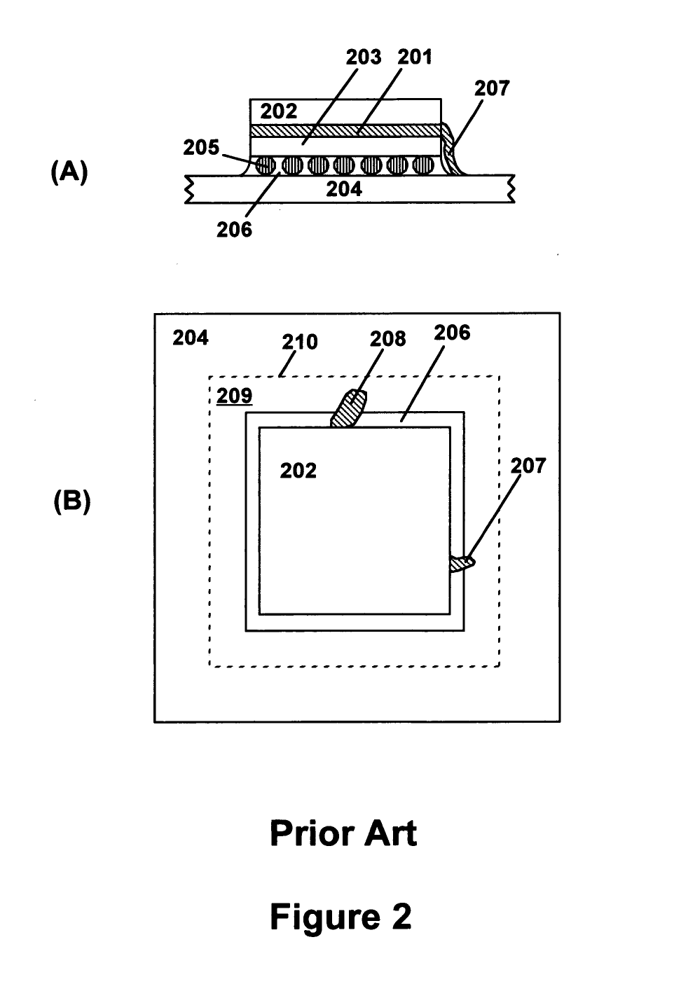

FIG. 2 illustrates the effects of bleed out or squeeze out of solder from a thermal interface for a BGA device. FIG. 2(A) depicts a side view of a typical prior art thermal interface 201 between a heat sink 202 and an IC chip 203 attached to a substrate 204 via an array of solder balls 205 that are reinforced and protected by a resin underfill 206. FIG. 2(A) also depicts a solder pool 207 that has bled out or been squeezed out of thermal interface 201 and past resin underfill 206 onto the surface of substrate 204. FIG. 2(B) depicts a top view also showing a second solder pool 208 that has bled out or been squeezed out of thermal interface 201 and past resin underfill 206 onto the surface of substrate 204. In order to avoid electrically shorting adjacent discrete components (or other IC chips) mounted on substrate 204, a “keep out area” 209 defined by dashed line 210 is typically designated, within which other circuit elements may not be mounted. The necessity of designating a relatively large “keep out area” to avoid the possibility of electrical shorting by molten solder from a thermal interface wastes valuable microelectronic real estate.

The present invention provides an improved thermal interface between an integrated circuit (IC) chip and a heat sink, comprising: a layer of a solder material sandwiched between and bonded to the IC chip and the heat sink; and a metallic grid embedded in the layer of the solder material. The solder material must have a fusion temperature that is higher than a predetermined maximum operating temperature of the IC chip so that the thermal interface remains solid during operation of the IC circuit. Preferred solder materials include indium and indium alloys. Other suitable solder materials, depending on the IC chip operating temperature and the bonding characteristics of the IC chip and the heat sink material, include tin-lead alloys, tin-silver alloys, tin-silver-copper alloys, and tin-lead-silver alloys. In addition, the metal comprising the metallic grid must have a fusion temperature higher than the fusion temperature of the solder material so that the metallic grid remains substantially intact when the solder material is reflowed to form a preform and/or a thermal interface of the invention. A preferred metallic grid material is copper. Other metals that may be used for the metallic grid of the invention include copper alloys, brass alloys, bronze alloys, and stainless steels.

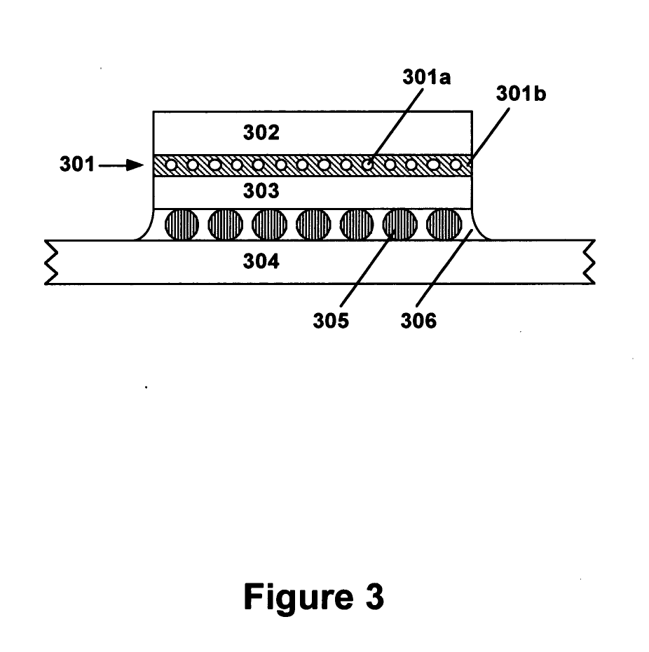

FIG. 3 depicts a side view of a thermal interface 301 of the invention connecting a heat sink 302 and an IC chip 303, which is attached to a substrate 304 via an array of solder balls 305 that are reinforced and protected by a resin underfill 306. Thermal interface 301 comprises a metallic grid 301a embedded in a layer of a solder material 301b that is sandwiched between and bonded to heat sink 302 and IC chip 303. The bonds between layer of solder material 301b and heat sink 302 and between layer of solder material 301b and IC chip 303 are preferably formed by reflowing the solder material comprising layer 301b.

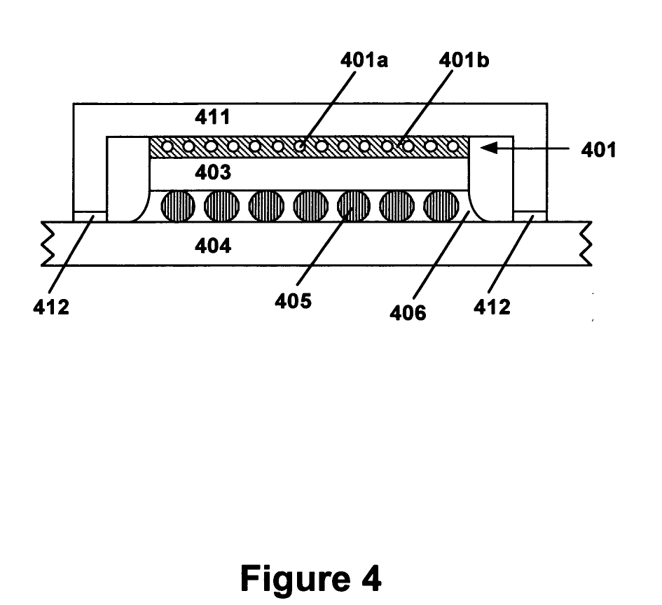

FIG. 4 depicts a side view of a thermal interface 401 of the invention connecting a heat spreader 411 to an IC chip 403, which is attached to a substrate 404 via an array of solder balls 405 that are reinforced and protected by a resin underfill 406. Thermal interface 401 comprises a metallic grid 401a embedded in a layer of a solder material 401b that is sandwiched between and bonded to heat spreader 411 and IC chip 403. The bottom edge of heat spreader 411 is sealed to substrate 404 via a seal 412 so as to encapsulate the BGA device to protect IC chip 403 from environmental degradation. To avoid solder squeeze out during the reflow process, thermal interface 401 must resist compression due to the weight of heat spreader 411 (and pressure from any holddown spring used) until the material of seal 412 hardens. This is typically accomplished by including a relatively long preheat time in the reflow process to cure the material of seal 412 before the temperature is ramped up to reflow solder material 401b. The resistance to compression provided by metallic grid 401a of the invention, however, obviates the need to harden the material of seal 412, enabling the preheat time to be shortened. For example, a typical heat spreader attach profile of 90 minutes (including cool down) may be reduced to 45 minutes.

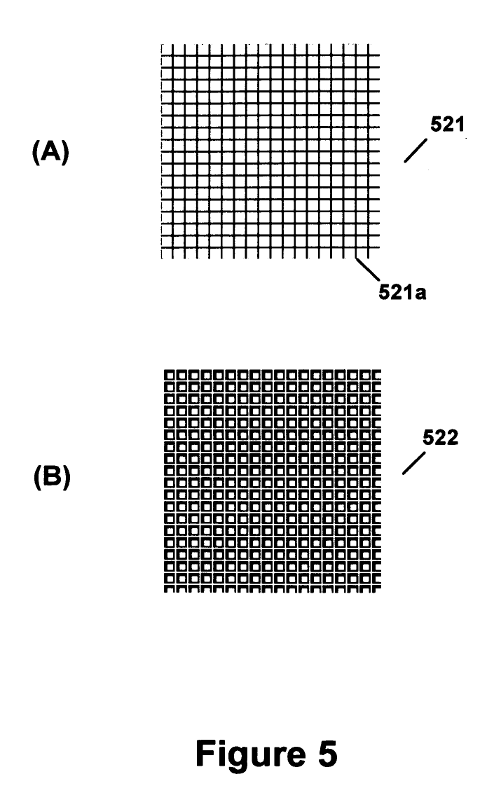

FIG. 5 illustrates two types of metallic grids suitable for use in the thermal interface of the invention. FIG. 5(A) depicts a metallic grid comprising a wire mesh 521 comprising strands of wire 521a that are woven together or otherwise bound together to form a mesh. Within the scope of the invention, the wire diameter and wire density may be varied within wide ranges. FIG. 5(B) depicts a metallic grid comprising a perforated metal foil 522 having a plurality of square holes (white areas). The holes or openings in the perforated metal foil may be any suitable shape, square or circular, for example, and may be produced by any suitable means, metal expansion and rolling, laser milling or die punching, for example. Within the scope of the invention, the foil thickness, hole size and hole density may be varied within wide ranges.

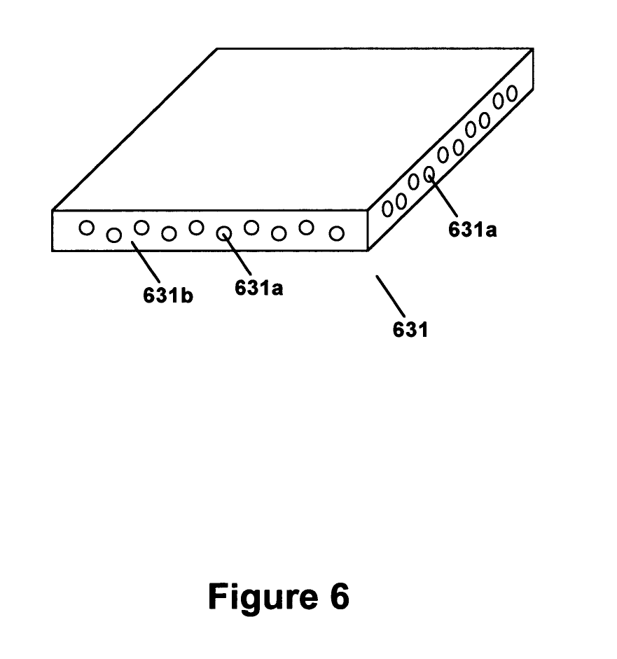

The invention further provides a preform for fabricating a thermal interface between an IC chip and a heat sink, comprising: a sheet of a solder material that has a fusion temperature higher than a predetermined maximum operating temperature of the IC chip; and a metallic grid embedded in the sheet of the solder material and comprising a metal having a fusion temperature higher than the fusion temperature of the solder material. The solder material of the preform is selected to provide strong bonds to the IC chip and the heat sink when the preform is sandwiched therebetween and heated to the fusion temperature of the solder material in the presence of a soldering flux. FIG. 6 depicts a preform 631 of the invention comprising a wire mesh 631a embedded in a layer of a solder material 631b.

The invention further provides a method of fabricating the preform of the invention for providing a thermal interface between an IC chip and a heat sink, comprising the steps of: providing a solder material that has a fusion temperature higher than a predetermined maximum operating temperature of the IC chip, and bonds to the semiconductor chip and the heat sink when heated to the fusion temperature of the solder material in the presence of a soldering flux; providing a metallic grid of a metal having a fusion temperature higher than the fusion temperature of the solder material; and embedding the metallic grid in the solder material. The metallic grid may be embedded in the solder material by any suitable method.

One method of embedding the metallic grid in the solder material involves reflow soldering in the presence of a flux and comprises the steps of: providing a sheet of the solder material; applying a soldering flux to at least a portion of the surface of the metallic grid, the sheet of the solder material, or both the metallic grid and the sheet of the solder material; placing the metallic grid and the sheet of the solder material in contact to form a layered preform precursor; and heating the layered preform precursor to the fusion temperature of the solder material.

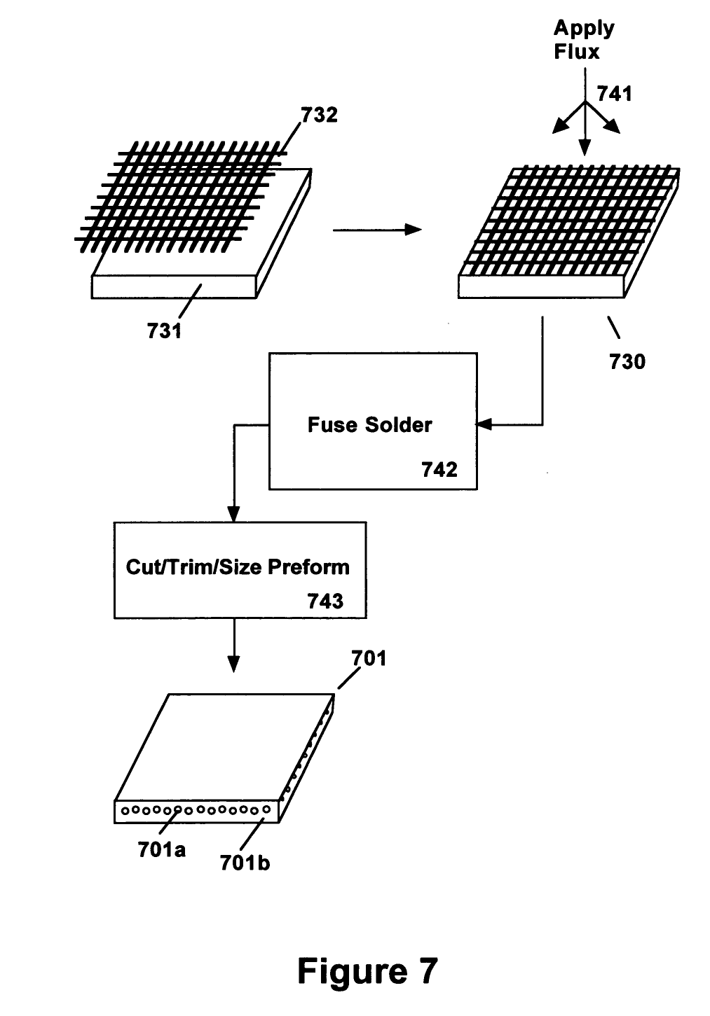

FIG. 7 illustrates a preferred method for embedding a metallic grid 701a in a layer of a solder material 701b by reflow soldering in the presence of a soldering flux to provide a preform 701 for use in fabricating the thermal interface of the invention. In this method, a sheet of the solder material 731 and a metallic grid 732 are placed in contact to form a layered preform precursor 730. The soldering flux may be applied by any suitable means to at least a portion of the surface of the metallic grid, the sheet of the solder material, or both. As depicted in FIG. 7, a preferred approach is to spray the soldering flux, via a flux applicator 741, onto the metallic grid of layered preform precursor 730, which is in contact with the sheet of the solder material of layered preform precursor 730 so that both the metallic grid and the sheet of solder material of layered preform precursor 730 are fluxed. Other suitable methods for applying the soldering flux include dipping, brushing and foaming, for example. Layered preform precursor 730 is heated via a heating device 742 to at least the fusion temperature of the solder material so as to reflow the solder material and embed the metallic grid therein. Heating device 742 is preferably a reflow oven but any suitable heating device may be used. The flux should be selected depending on the type of solder material to be used and the condition of the IC chip and heat sink surfaces to be bonded. Commonly available soldering flux types include R flux (rosin non-activated), RMA flux (rosin mildly activated), RA flux (rosin activated), WSOA flux (water soluble organic acid), and WSIOA flux (water soluble inorganic acid).

As also indicated in FIG. 7, the preform may optionally need to be cut from a larger sheet, trimmed to remove dangling mesh wires that could create electrical shorts, and/or sized to fit the IC chip and the heat sink. Such shaping operations are preferably performed by an automated machine 743 and may include cutting, slicing, stamping, die punching, and combinations thereof.

Another method of embedding the metallic grid in the solder material comprises the steps of: providing a sheet of the solder material; placing the metallic grid and the sheet of the solder material in two contacting layers; and applying pressure across the two contacting layers so as to press the metallic grid into the sheet of the solder material so as to provide a composite structure. Pressure may be applied by any suitable means, including platens (driven by a press) and rollers in a roller mill. The preform provided by this method may be used directly to fabricate the thermal interface of the invention, or may be reflowed to more completely embed the metallic grid in the solder material. In the latter case, the method of embedding the metallic grid in the solder material further comprises the steps of applying a soldering flux to at least a portion of the surface of the composite structure; and heating the composite structure with the applied soldering flux to at least the fusion temperature of the solder material.

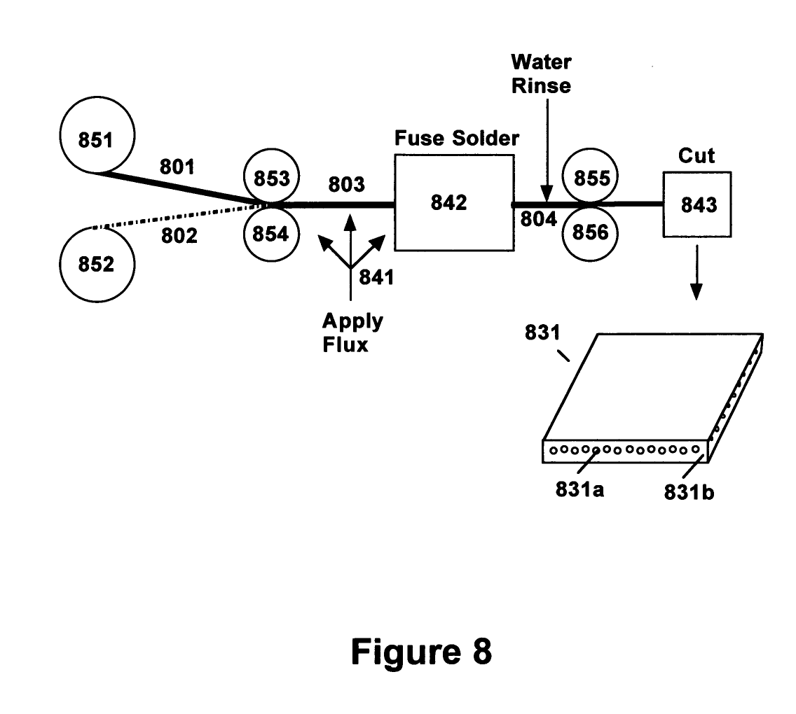

FIG. 8 depicts fabrication of the preform of the invention by a ribbon to ribbon compression and reflow process. In this process, a ribbon 801 of the solder material fed from reel 851 and a ribbon 802 of the metallic grid fed from reel 852 are pressed together by rollers 853 and 854 in a roller mill to form a composite ribbon 803. A soldering flux is applied to composite ribbon 803 via flux applicator 841 before composite ribbon 803 passes through reflow oven 842, where the solder material fuses and embeds the metallic grid of ribbon 802 to form a preform ribbon 804. Depending on the type of flux used, an optional water rinse may be needed to remove flux residues. If necessary, preform ribbon 804 may be milled by passing through rollers 855 and 856 to provide the desired preform thickness. Preform ribbon 804 is die punched, sliced, stamped or otherwise cut or shaped to provide preforms 831 having a metallic grid 831a embedded in layer of a solder material 831b. In an alternative embodiment, preforms are cut directly from composite ribbon 803 without reflow so that reflow oven 842, rollers 855 and 856, and the water rinse are not needed.

Another method of embedding the metallic grid within the solder material to provide a preform according to the invention is to deposit the solder material onto the metallic grid as a coating. The solder material may be deposited on the metallic grid by any suitable means, including dip coating (from molten solder), electrodeposition from an aqueous or nonaqueous plating solution, vapor deposition, and combinations thereof. The thickness of the solder material deposited on the metallic grid by dip coating from molten solder may be adjusted via the type of soldering flux applied to the metallic grid prior to dip coating, the preheat temperature of the fluxed metallic grid, the temperature of the molten solder, the rate of withdrawal of the metallic grid from the molten solder, and the time the metallic grid is immersed in the molten solder, for example. Electrodeposited and vapor deposited coatings of the solder material may be reflowed to fill in the holes in the metallic grid and/or provide a more uniform coating.

The invention also provides a method for fabricating the thermal interface of the invention, which involves sandwiching a preform of the invention between and in contact with an IC chip and a heat sink to form a thermal interface precursor, and heating the thermal interface precursor to at least the fusion temperature of the solder material in the presence of a soldering flux. This method comprises the steps of: providing a preform comprising a metallic grid embedded in a sheet of a solder material that has a fusion temperature higher than a predetermined maximum operating temperature of the IC chip, and bonds to the IC chip and the heat sink when the preform is sandwiched therebetween and heated to the fusion temperature of the solder material in the presence of a soldering flux; applying a soldering flux to at least one of the IC chip, the heat sink, and the two sides of the preform; placing the preform between and in contact with the IC chip and the heat sink to provide a thermal interface precursor; and heating the thermal interface precursor to a predetermined temperature higher than the fusion temperature of the solder material. The metallic grid must comprise a metal having a fusion temperature higher than the fusion temperature of the solder material.

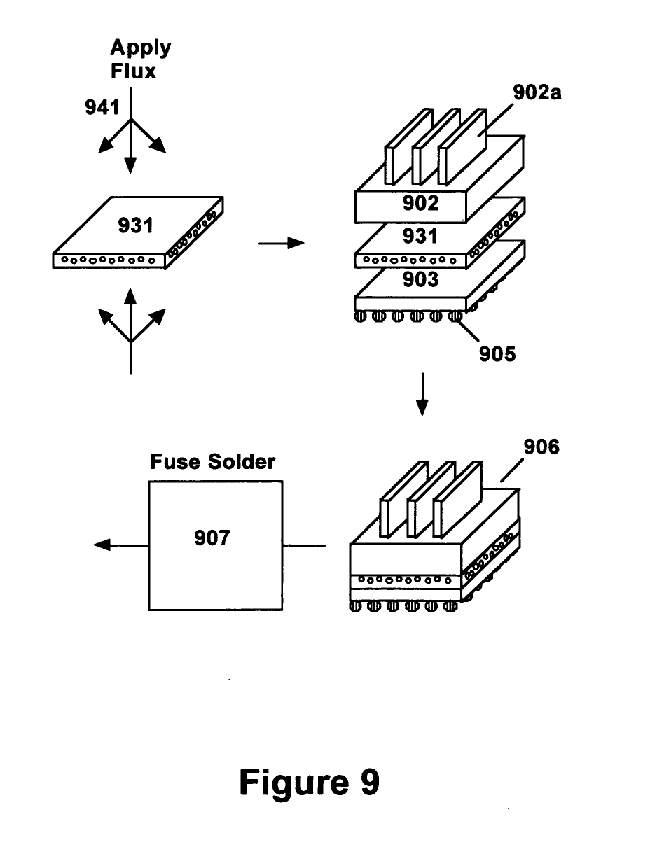

FIG. 9 depicts fabrication of the thermal interface of the invention using a preform 931 according to the invention. A soldering flux is preferably applied to both sides of preform 931 via flux applicator 941. The soldering flux is preferably applied by spraying but may be applied by any suitable means. Preform 931 with applied flux is sandwiched between a heat sink 902 and an IC chip 903 (packaged as a BGA device) to form a thermal interface precursor 906. The soldering flux may alternatively or additionally be applied to heat sink 902 and/or IC chip 903, and different types of soldering fluxes may be used to accommodate differences in solderability, between heat sink 902 and IC chip 903, for example. Heat sink 902 is depicted with radiator fins 902a in FIG. 9 but heat sink 902 may be of any suitable type. Thermal interface precursor 906 is preferably passed through a reflow oven 907 to fuse the solder material of the preform and bond the thermal interface to heat sink 902 and IC chip 903. Suitable conveyorized reflow ovens having programmable heat zones are well-known in the art.

Integrated circuit chip 903 of FIG. 9 is attached to a substrate (not shown), a circuit board or a chip carrier, for example, via solder balls 905. Preferably, the BGA attachment and the thermal interface formation are performed in the same reflow process (one pass through a reflow oven) but may be performed in separate reflow processes (two passes through the reflow oven). For separate reflow processes, the higher temperature process is preferably performed first.

A concern when a preform of the invention is cut from a larger sheet or otherwise shaped to fit a specific IC chip and heat sink is that a wire from an embedded metal mesh may be dislodged during the cutting or shaping operation. Such a stray wire, which may produce an electrical short in the IC chip or an adjacent circuit component, can result when the preform is cut along a line that substantially coincides with one of the embedded wires. Note that stray wires are not a concern when the embedded metallic grid comprises a perforated metal foil.

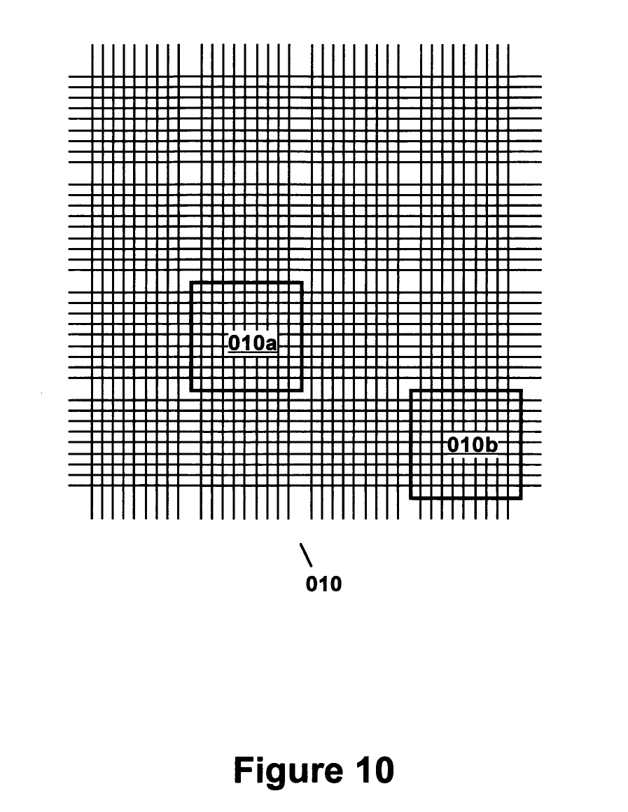

FIG. 10 depicts a metal mesh 010 having periodically varied wire pitch to avoid stray wires during fabrication of preforms according to the invention. In this case, the preforms are cut along lines for which there is one or more missing mesh wires, as indicated by areas 010a and 010b, so that cutting along a line that substantially coincides with one of the embedded wires is avoided.

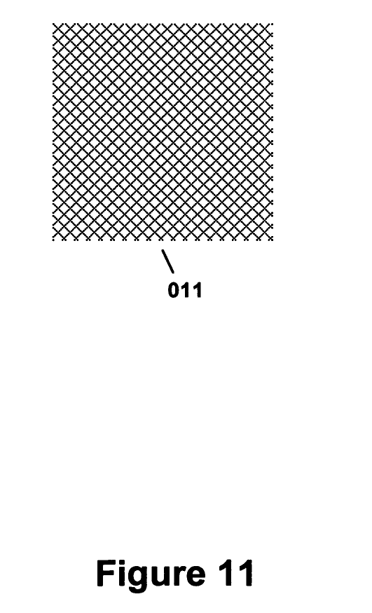

FIG. 11 depicts a metal mesh 011 that is bias cut to avoid stray wires during fabrication of the preform of the invention. In this case, cutting of the embedded wires always occurs at an angle (45° in FIG. 11) so that the possibility of producing stray wires is avoided. Other preform cutting geometries and methods for avoiding stray wires will be apparent to those skilled in the art.

### DESCRIPTION OF A PREFERRED EMBODIMENT

A preform of the invention, as depicted in FIG. 6, typically has x-y dimensions that range from 0.4 to 1.0 inch (10 to 25 mm) and a z-dimension that ranges from 0.005 to 0.010 inch (0.1 to 2.5 mm). A preferred metallic grid of the invention comprises a 100-mesh woven copper mesh (also known as copper cloth or copper screen) comprising 100 copper wires per inch that are 4.5 mils in diameter and continuous in the x-y direction. A preferred solder material for use in the invention comprises indium or an indium alloy.

### Example 1

### Feasibility Demonstration

A piece of 100×100 mesh copper screen (Dorstener Wire Technology) approximately 6×12 mm on the sides was placed on a ceramic coupon and one drop of Kester #186 RMA flux was added. Approximately half of the area of the copper screen was covered with a piece of indium foil that was 7 mils (0.2 mm) thick. When this assembly was placed on a hot plate set at 200° C., the indium foil reflowed and wet the copper screen well. A rigid metal plate was placed on the reflowed assembly and hit with a hammer to simulate a milling operation to smooth out observed unevenness in the reflowed indium surface. Micrometer measurements indicated that the uncoated portion of the copper screen was 9 mils thick, whereas the portion of the copper screen embedded in indium was 12 mils thick.

### Example 2

### Simulated Thermal Interface Test

Formation of the interface of the invention was demonstrated using a test structure comprising rectangular pieces (1.0×1.5 cm) of a pure indium foil (9 mils thick) and a 100×100 mesh copper screen sandwiched between first and second coupons of FR-4 laminate material coated with an ENIG (electroless nickel immersion gold) coating. The procedure was as follows. An aliquot (5 μL) of Kester #186 RMA flux was pipetted onto the top of the first coupon. The piece of copper screen was placed on the fluxed surface of the first coupon, and the piece of indium foil was placed on the copper screen. An aliquot (5 μL) of Kester #186 RMA flux was pipetted onto the top of the indium foil. The second coupon was placed on top of the fluxed indium foil. This test structure, held together with a spring clip, was passed through a reflow oven having a four-minute temperature profile that peaked at 170° C. The reflowed indium wetted all solderable surfaces well, embedding the copper screen and bonding to the ENIG surfaces of the coupons.

### Example 3

### Pressure Embedded Copper Grid

The feasibility of pressing a metallic grid into a solder material to form the thermal interface of the invention was demonstrated using the test structure, soldering flux and reflow conditions of Example 2. In the present case, the copper screen was first treated in Kester #5520 Copper-Nu™ to remove surface oxides, and was then rinsed and dried. The deoxidized copper screen was then dipped in the soldering flux and dried in warm flowing air to remove flux volatile materials. This pre-fluxed copper screen was then pressed into the indium foil by roller milling to form a preform. An aliquot (5 μL) of Kester #186 RMA flux was pipetted onto both sides of the preform, which was then sandwiched between the first and second coupons. This test structure, held together with a spring clip, was passed through a reflow oven having a four-minute temperature profile that peaked at 170° C. The reflowed indium wetted all solderable surfaces well, embedding the copper screen and bonding to the ENIG surfaces of the coupons.

A preferred method for fabricating the preform of the invention is the ribbon to ribbon compression and reflow process illustrated in FIG. 8, which involves a metallic grid ribbon and a solder material ribbon. The metallic grid ribbon preferably comprises a plain weave 120×120 copper wire mesh comprising wires 3.7 mils in diameter. The width of the metallic grid ribbon is preferably sized to match the desired width of the final preform. At regular intervals, corresponding to the desired length of the final preform, from 2 to 20 cross-ribbon wires are preferably omitted from the copper mesh to enable cutting preforms from the copper mesh ribbon without producing stray wires. The copper mesh ribbon is preferably first deoxidized by applying Kester #5520 Copper-Nu™ solution, for example, followed by water rinsing and drying. The copper mesh ribbon is preferably fluxed by application of a non-corrosive rosin flux (Kester #186 RMA flux, for example), followed by evaporation of the flux volatile components. The fluxed copper mesh ribbon and the solder material ribbon, which is preferably 6 mils thick and of slightly less width than the copper mesh ribbon, are pressed together between rollers in a roller mill set to a thickness less than the combined thicknesses of the two ribbons. If necessary, a second roller mill may be used to provide the desired final thickness of the combination ribbon, which is sliced in areas with omitted cross-ribbon wires to provide preforms according to the invention. Preforms are preferably placed in a tape and reel carrier with a heat-sealed cover tape to facilitate dispensing from an automated pick and place machine. Use of 6-mil thick indium solder material with a copper mesh screen according to this preferred embodiment (instead of the 9-mil thick indium foil typically used to fabricate prior art thermal interfaces) provides significant cost savings.

The preferred embodiments of the present invention have been illustrated and described above. Modifications and additional embodiments, however, will undoubtedly be apparent to those skilled in the art. Furthermore, equivalent elements may be substituted for those illustrated and described herein, parts or connections might be reversed or otherwise interchanged, and certain features of the invention may be utilized independently of other features. Consequently, the exemplary embodiments should be considered illustrative, rather than inclusive, while the appended claims are more indicative of the full scope of the invention.

We claim:

1. A thermal interface between an IC chip and a heat sink, comprising:
a layer of a solder material sandwiched between and bonded to the IC chip and the heat sink; and
a metallic grid embedded in the layer of the solder material,
wherein the solder material has a fusion temperature that is higher than a predetermined maximum operating temperature of the IC chip, and the metallic grid comprises a metal having a fusion temperature higher than the fusion temperature of the solder material.

2. The thermal interface of claim 1, wherein the solder material is selected from the group consisting of indium, indium-tin alloys, tin-lead alloys, tin-silver alloys, tin-silver-copper alloys, and tin-lead-silver alloys.

3. The thermal interface of claim 1, wherein the metallic grid comprises a metal selected from the group consisting of copper, copper alloys, brass alloys, bronze alloys, and stainless steels.

4. The thermal interface of claim 1, wherein the metallic grid comprises woven metal wires.

5. The thermal interface of claim 1, wherein the metallic grid comprises a perforated metal foil.

6. A preform for providing a thermal interface between an IC chip and a heat sink, comprising:
a sheet of a solder material that has a fusion temperature higher than a predetermined maximum operating temperature of the IC chip; and
a metallic grid embedded in the sheet of the solder material and comprising a metal having a fusion temperature higher than the fusion temperature of the solder material,
wherein the solder material of the preform bonds to the IC chip and the heat sink when the preform is sandwiched therebetween and heated to the fusion temperature of the solder material in the presence of a soldering flux.

7. The preform of claim 6, wherein the solder material is selected from the group consisting of indium, indium-tin alloys, tin-lead alloys, tin-silver alloys, tin-silver-copper alloys, and tin-lead-silver alloys.

8. The preform of claim 6, wherein the metallic grid comprises a metal selected from the group consisting of copper, copper alloys, brass alloys, bronze alloys, and stainless steels.

9. The preform of claim 6, wherein the metallic grid comprises woven metal wires.

10. The preform of claim 6, wherein the metallic grid comprises a perforated metal foil.

11. A method of fabricating a preform for providing a thermal interface between an IC chip and a heat sink, comprising the steps of:
providing a solder material that has a fusion temperature higher than a predetermined maximum operating temperature of the IC chip, and bonds to the IC chip and the heat sink when sandwiched therebetween and heated to the fusion temperature of the solder material in the presence of a soldering flux;
providing a metallic grid of a metal having a fusion temperature higher than the fusion temperature of the solder material; and
embedding the metallic grid in the solder material.

12. The method of claim 11, wherein the step of embedding the metallic grid in the solder material comprises the steps of:
providing a sheet of the solder material;
applying a soldering flux to at least a portion of the surface of the metallic grid, the sheet of the solder material, or both the metallic grid and the sheet of the solder material;
placing the metallic grid and the sheet of the solder material in contact to form a layered preform precursor; and
heating the layered preform precursor to at least the fusion temperature of the solder material.

13. The method of claim 12, wherein the soldering flux is selected from the group consisting of R flux (rosin non-activated), RMA flux (rosin mildly activated), RA flux (rosin activated), WSOA flux (water soluble organic acid), and WSIOA flux (water soluble inorganic acid).

14. The method of claim 11, wherein the step of embedding the metallic grid within the solder material comprises the steps of:
providing a sheet of the solder material;
placing the metallic grid and the sheet of the solder material in two contacting layers; and
applying pressure across the two contacting layers so as to press the metallic grid into the sheet of the solder material so as to provide a composite structure.

15. The method of claim 14, further comprising the steps of:
applying a soldering flux to at least a portion of the surface of the composite structure; and
heating the composite structure with the applied soldering flux to at least the fusion temperature of the solder material.

16. The method of claim 11, wherein the step of embedding the metallic grid within the solder material comprises the step of:
depositing the solder material onto the metallic grid by a method selected from the group consisting of dip coating, electrodeposition, vapor deposition, and combinations thereof.

17. The method of claim 11, further comprising the step of:
shaping the preform,
wherein the preform is shaped using a method selected from the group consisting of cutting, slicing, stamping, die punching, and combinations thereof.

18. The method of claim 11, wherein the soldering flux is applied by a method selected from the group consisting of dip coating, spraying, foaming, and brushing.

19. A method of providing a thermal interface between an IC chip and a heat sink, comprising the steps of:
providing a preform comprising a metallic grid embedded in a sheet of a solder material that has a fusion temperature higher than a predetermined maximum operating temperature of the semiconductor chip, and bonds to the IC chip and the heat sink when the preform is sandwiched therebetween and heated to the fusion temperature of the solder material in the presence of a soldering flux;
applying a soldering flux to at least one of the IC chip, the heat sink, and the two sides of the preform;
placing the preform between and in contact with the IC chip and the heat sink to provide a thermal interface precursor; and
heating the thermal interface precursor to a predetermined temperature higher than the fusion temperature of the solder material,
wherein the metallic grid comprises a metal having a fusion temperature higher than the fusion temperature of the solder material.

20. The method of claim 19, wherein the soldering flux is selected from the group consisting of R flux (rosin non-activated), RMA flux (rosin mildly activated), RA flux (rosin activated), WSOA flux (water soluble organic acid), and WSIOA flux (water soluble inorganic acid).
